(19) United States
(12) Patent Application Publication
(10) Pub. No.: US 2007/0004182 A1
(43) Pub. Date: Jan. 4, 2007

(54) Methods and system for inhibiting immersion lithography defect formation

(75) Inventors: Ching-Yu Chang, Yilang City (TW); Burn Jeng Lin, Hsin-Chu (TW)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 11/280,162

(22) Filed: Nov. 16, 2005

Related U.S. Application Data
(60) Provisional application No. 60/695,825, filed on Jun. 30, 2005.

(51) Int. Cl. H01L 21/20; H01L 21/36

(52) U.S. Cl. 438/478; 438/947

(57) ABSTRACT

An immersion lithography system includes an immersion fluid holder for containing an immersion fluid. The system further includes a stage for positioning a resist-coated semiconductor wafer in the immersion fluid holder and a lens proximate to the immersion fluid holder and positionable for projecting an image through the immersion fluid and onto the resist-coated semiconductor wafer. The immersion fluid holder includes a coating configured to reduce contaminate adhesion from contaminates in the immersion fluid.

### CROSS-REFERENCE

This application claims priority from U.S. Provisional Patent Application Ser. No. 60/695,825, filed on Jun. 30, 2005, and entitled “METHODS AND SYSTEM FOR INHIBITING IMMERSION LITHOGRAPHY DEFECT FORMATION.”

### BACKGROUND

Immersion lithography typically involves applying a coating of photoresist on a top surface (e.g., a thin film stack) of a semiconductor wafer and subsequently exposing the photoresist to a pattern. During exposure, de-ionized (DI) water may be used to fill the space between the exposure lens and the resist surface to increase the depth of focus (DOF) window. One or more post-exposure bakes and/or other processes may then be performed, such as to allow the exposed photoresist to cleave (such as when the photoresist comprises a polymer-based substance), to densify the polymer, and/or to evaporate any solvent, among other possible objectives. A developing chamber may then be employed to remove exposed polymer, which can be soluble to an aqueous developer solution, possibly after application of tetra-methyl ammonium hydroxide (TMAH). A DI water rinse may then be applied to remove the water-soluble polymer or other dissolved photoresist, and a spin dry process may be used to dry the wafer. The exposed and developed wafer may then be transferred for subsequent processing operations, although possibly after additional baking to evaporate moisture on the resist surface.

Immersion lithography apparatus may comprise an immersion scanner DI chamber, which may include a lens system, a DI water holder system around the lens, a sensor system and/or a wafer stage system, among other possible components. Portions of the lens apparatus may be composed of silica, silicon dioxide and/or similar materials, and/or may have one or more layers of silica, silicon dioxide and/or similar materials coated thereon. The stage system may be composed of an alloy of aluminum, silica, silicon, magnesium, zinc, phosphorus, and/or oxygen. The sensor system surface may be coated with titanium nitride. The DI water holder system may be composed of stainless steel.

The above-described processing/apparatus can be encumbered by several problems. For example, the resist surface zeta potential can be about −40 mV at PH=7 (zeta potential may refer to the electrical potential that exists across the interface of a solid and a liquid, or the potential of a solid surface interacting with an ambient featuring a specific chemical composition, and may also be referred to as electrokinetic potential). Consequently, if the immersion DI fluid contains contaminates, the contaminates may adhere to the resist surface. Similarly, the silica, silicon dioxide or similar material of the lens and/or lens apparatus may have a zeta potential of about −25 mV, which can be weaker than the resist surface, thus possibly attracting contaminants. The alloyed material of the stage may contain at least one aluminum element or component which may have a +40 mV zeta potential, such that its surfaces may easily adhere negative zeta potential particles. The stainless steel of the DI water holder system may also have a positive zeta potential, such that negative zeta potential particles may adhere thereto.

### BRIEF DESCRIPTION OF THE DRAWINGS

Aspects of the present disclosure are best understood from the following detailed description when read with the accompanying figures. It is emphasized that, in accordance with the standard practice in the industry, various features may not be drawn to scale. In fact, the dimensions of the various features may be arbitrarily increased or reduced for clarity of discussion.

FIGS. 1 and 2 are sectional views of a wafer being processed by conventional immersion lithography methods/apparatus.

FIG. 3 illustrates several exemplary defects on a wafer which may result from conventional immersion lithography methods/apparatus.

FIGS. A-F graphically depict relationships between zeta potential and pH for various compositions/wafers.

FIG. 4 depicts a contact angle of about 20 degrees of a fluid such as de-ionized water on a surface coated with silicon dioxide.

FIG. 5 depicts a contact angle of about 90 degrees of a fluid such as de-ionized water on a surface coated with PTFE or polytetrafluoroethylene.

FIGS. 6 and 7 are sectional views of a wafer being processed by conventional immersion lithography methods/apparatus.

FIGS. 8 and 9 are sectional views of a wafer being processed by one embodiment of immersion lithography apparatus according to aspects of the present disclosure.

FIG. 10 is a flow chart of at least a portion of one embodiment of a method for implementing an immersion lithography process with reduced defects according to aspects of the present disclosure.

### DETAILED DESCRIPTION

The entire disclosures of the following patents are hereby incorporated herein by reference:
(1) U.S. Pat. No. 6,867,884;
(2) U.S. Pat. No. 6,809,794;
(3) U.S. Pat. No. 6,788,477;
(4) U.S. Pat. No. 5,879,577;
(5) U.S. Pat. No. 6,114,747; and
(6) U.S. Pat. No. 6,516,815.

The entire disclosures of the following U.S. patent applications related hereto and commonly assigned herewith are also hereby incorporated herein by reference:
(7) U.S. Ser. No. 10/995,693, entitled “Immersion Photolithography With Megasonic Rinse,” Attorney Docket No. 24061.536;
(8) U.S. Ser. No. 11/025,538, entitled “Supercritical Developing For A Lithographic Process,” Attorney Docket No. 24061.565;
(9) U.S. Ser. No. 60/695,562, entitled “Immersion Lithography Defect Reduction,” Attorney Docket No. 24061.656; and
(10) U.S. Ser. No. 60/695,826, entitled “Immersion Lithography Defect Reduction,” Attorney Docket No. 24061.657.

It is to be understood that the following disclosure provides many different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

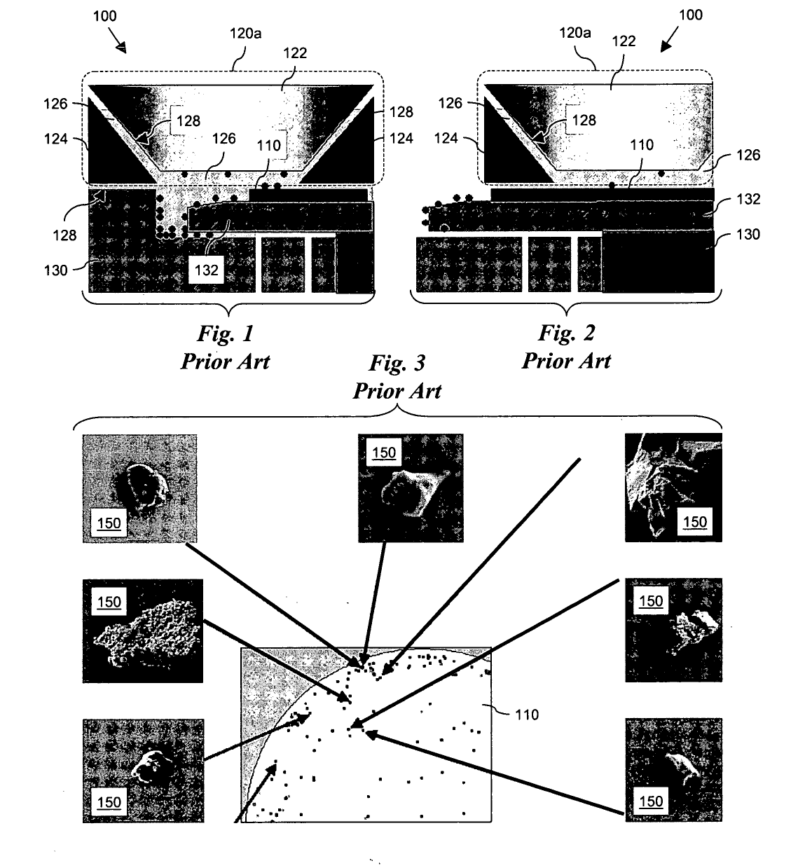

Referring to FIGS. 1 and 2, illustrated are sectional views of conventional immersion lithography apparatus 100 in which different regions of a semiconductor wafer 110 is undergoing immersion lithography processing. The semiconductor wafer 110 may include a substrate and a patterning layer. The substrate can include one or more layers, including poly, metal, and/or dielectric, that are desired to be patterned. The patterning layer can be a photoresist (resist) layer that is responsive to an exposure process for creating patterns.

The illustrated example of the immersion lithography apparatus 100 includes a lens system 122, a structure 124 for containing an immersion fluid 126 such as de-ionized water, various apertures 128 through which fluid can be added or removed, and a stage 130 and fixture 132 (such as a chuck, and which may be integral to the stage 130) for securing and moving the wafer 110 relative to the lens system 122. The immersion fluid containing structure 124 and the lens system 122 make up an immersion head 120a. The immersion head 120a can use some of the apertures 128 as an “air knife” which can purge air into the wafer for drying, and other apertures for removing any purged fluid. The air knife alone may be insufficient to purge all of the immersion fluid 126 from the wafer 110.

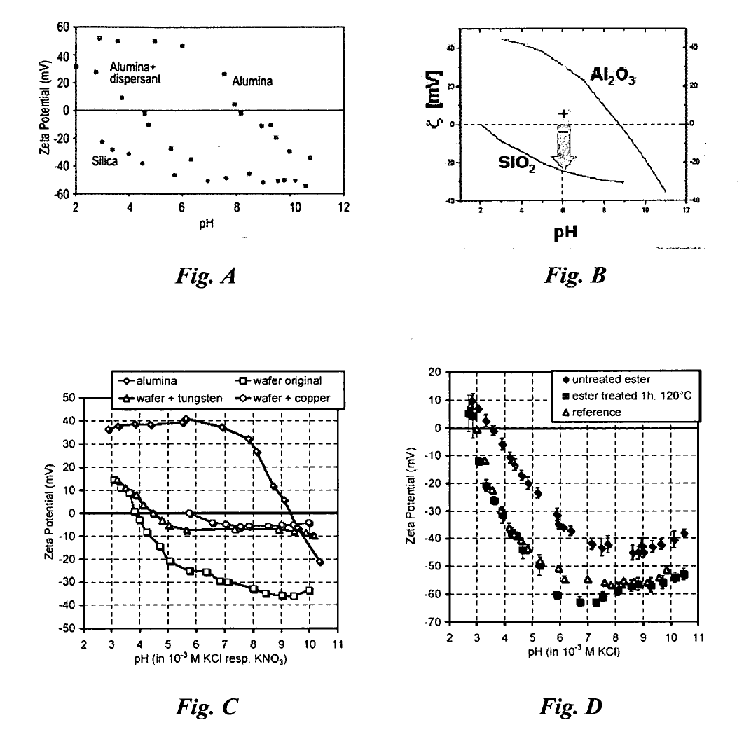

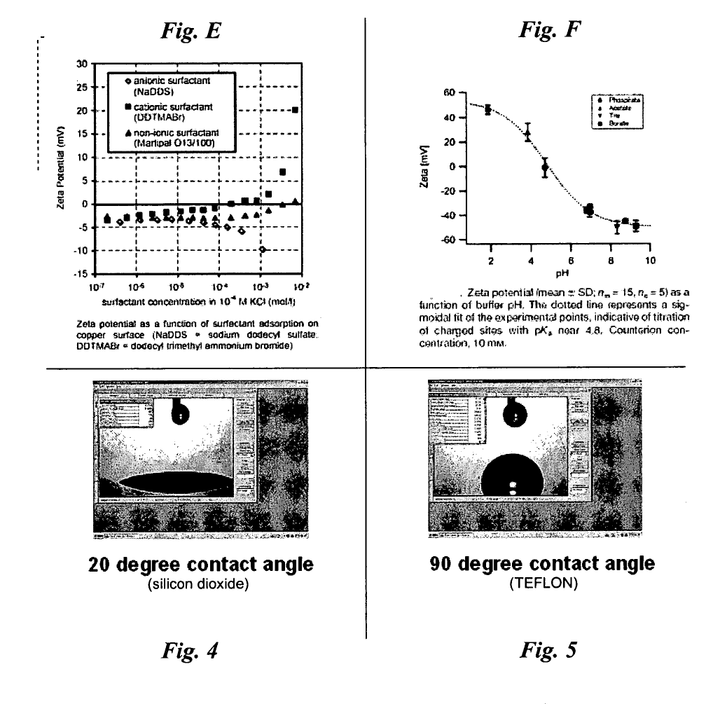

FIG. 3 includes a top view of the wafer 110 after undergoing conventional immersion lithography processing, such as via processing in the apparatus 100 shown in FIGS. 1 and 2. FIG. 3 also includes several detail views of defects 150 that may form on the wafer 110 during the processing in the apparatus 100. The defects can represent watermarks, residue or foreign particles in the patterned resist, or can represent deformation or “holes” (missing patterns) in the resist. Other types of defects may also exist. It is noted that if post-exposure bake (PEB) is increased in time or temperature to remove the watermark type defect, the likelihood of foreign particles and/or other defects may increase.

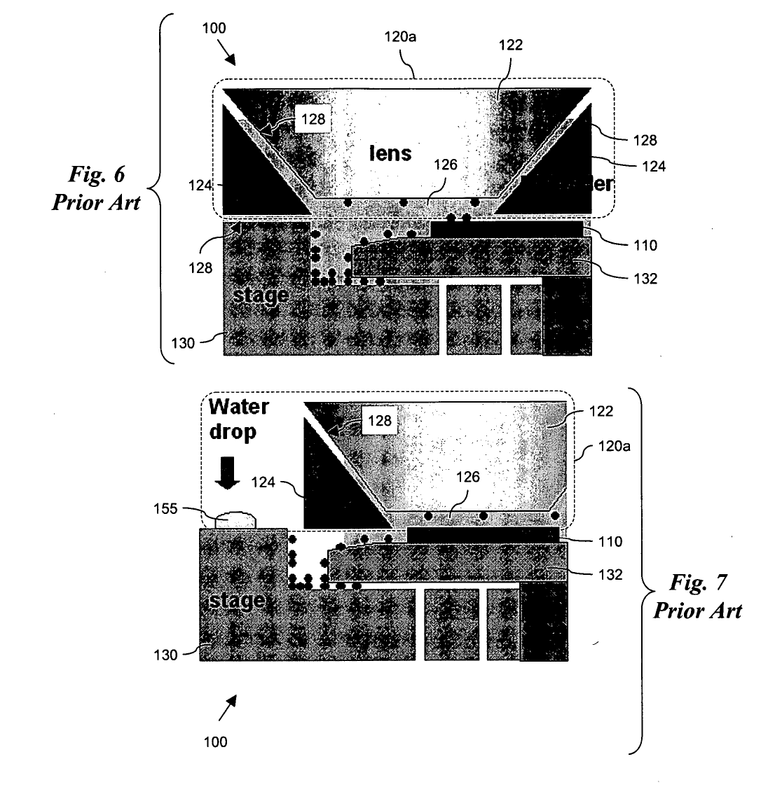

FIGS. 6 and 7 are additional sectional views of the apparatus 100 shown in FIGS. 1 and 2 and the wafer 110 shown in FIGS. 1-3. As described above, the composition or surface characteristics of one or more components of the apparatus 100 can have an affinity to adhere contaminates. For example, the silica or silicon dioxide composition of the stage 130 may have a relatively low contact angle (see FIG. 4) or be hydrophilic, such that particulate, water droplets 155 (possibly containing particulate), and/or other contaminates can adhere to surfaces of the stage 130. The composition, contact angle, affinity to water, and/or other aspects of the stage 130, fixture 132, lens 122, structure 124, and/or other components of the apparatus 100 may similarly render the surfaces thereof as being prone to the adherence of contaminates.

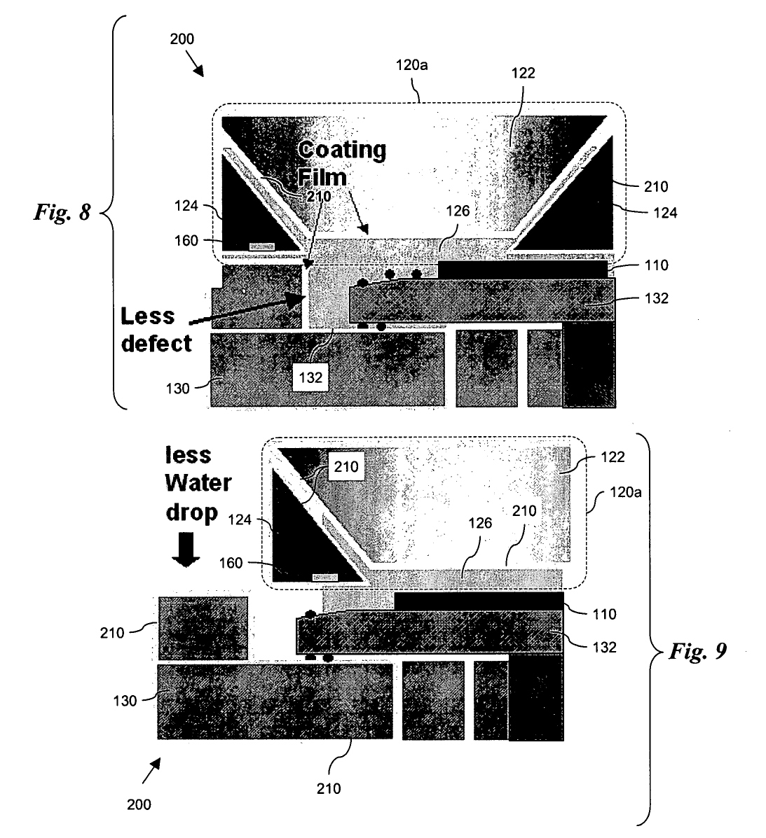

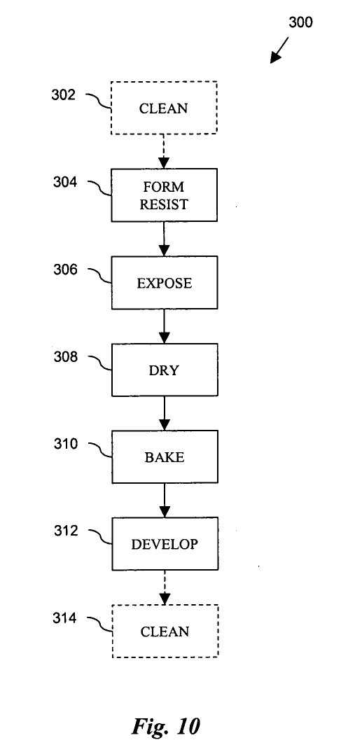

Referring to FIGS. 8 and 9, illustrated are sectional views of at least a portion of one embodiment of apparatus 200 according to aspects of the present disclosure. The apparatus 200 may be substantially similar to embodiments of the apparatus 100 shown in FIGS. 1, 2, 6 and 7. However, in the apparatus 200, a coating, lining or other layer 210 exists on one or more surfaces of one or more components of the apparatus 200. For example, one or more surfaces of the lens 122 may include the coating 210. In one embodiment, several or all surfaces of the lens 122 includes the coating 210, except possibly for the surfaces (e.g., top and bottom) through which exposure light propagates. One or more surfaces of the stage 130, the fixture 132, the immersion fluid containing structure 124, and/or the apertures 128 may also or alternatively include the coating 210. In one embodiment, all surfaces of all components of the apparatus 200 which may come in contact with the immersion fluid 126 (except possibly for the light-propagating surfaces of the lens 122) may include the coating 210.

The coating 210 may comprise one or more layers of silicon dioxide, polytetrafluoroethylene (“PTFE”, or TEFLON as provided by the DuPont Corp.), fluoride, polyethylene, polyvinylchloride, polymers of at least one of such materials, alloys of at least one of such materials, combinations containing at least one of such materials, and/or other polymers, among other compositions within the scope of the present disclosure. The coating 210 may be referred to as a “hydrophilic coating” because it provides improved wettability. In addition or in the alternative, the coating can be referred to as a “reduced-contaminate-adhesion coating” because it decreases the adhesion of contaminates in the water to the corresponding surface. The coating 210 may be formed on the surfaces of the components of the apparatus 200 by one or more of myriad conventional and/or future-developed processes, such as chemical vapor deposition (CVD), dipping, brushing, spraying, stamping, casting, bonding, spin-on coating, electrodeposition, and others. The thickness of the coating 210 may vary within the scope of the present disclosure. Moreover, the thickness, composition, application process(es), and/or other aspects of the coating 210 may vary within a single embodiment. For example, the thickness and composition of the coating 210 on one component of the apparatus 200 may vary from the thickness and composition of the coating on another component of the apparatus 200.

As illustrated in the embodiment shown in FIGS. 8 and 9, the apparatus 200 may also include one or more sensors or a sensor system (herein referred to collectively as “sensor”) 160. The sensor 160 may be configured to detect contamination levels of immersion fluid 126, rinsing agents and/or other fluids/gases, numbers of cycles of exposure, number of cycles of filling and evacuating the immersion fluid containing structure 124, contamination levels of the substrate 110, and/or other characteristics, qualities, measurements, or aspects, which may be employed to assess the need to clean, filter, maintain and/or replace components of the apparatus 200 and/or fluid/gas sources (such as an immersion fluid source). The sensor 160 may be coupled to or integral to the immersion fluid containing structure 124, as in the illustrated embodiment. However, the sensor 160 may also or alternatively be integral to, or directly or indirectly coupled to, another component of the apparatus 200, such as the stage 130, the immersion head 120a, and/or the fixture 132, among other components. The sensor 160 may also include the exterior coating 210.

Referring to FIG. 10, illustrated is a flow-chart diagram of at least a portion of one embodiment of a method 300 for immersion lithography according to aspects of the present disclosure. In step 304, a resist is formed over the surface of a wafer substrate. The resist may be a negative or positive resist and may be of a material now known or later developed for this purpose. For example, the resist may be a one-, two- or multi-component resist system. The application of the resist may be done with spin-coating or another suitable procedure. Prior to the application of the resist, the wafer may be first processed to prepare it for the photolithography process. For example, the wafer may be cleaned, dried and/or coated with an adhesion-promoting material prior to the application of the resist.

At step 306, the immersion exposure step is performed. The wafer and resist are immersed in an immersion exposure liquid such as de-ionized water, and exposed to a radiation source through a lens. The radiation source may be an ultraviolet light source, for example a krypton fluoride (KrF, 248 nm), argon fluoride (ArF, 193 nm), or F2 (157 nm) excimer laser. The wafer is exposed to the radiation for a predetermined amount of time is dependent on the type of resist used, the intensity of the ultraviolet light source, and/or other factors. The exposure time may last from about 0.2 seconds to about 30 seconds, for example.

At step 308, a drying process is performed. The drying process may be performed in-situ with the previous or next processing step, or may be performed in a separate chamber. One or more drying processes can by used individually or in various combinations. For example, one or more liquids can be added for the drying process, such as supercritical CO₂, alcohol (e.g., methanol, ethanol, isopropanol (IPA), and/or xylene), surfactants, and/or clean de-ionized water. Alternatively, or additionally, one or more gases can be added for the drying step 308, such as condensed/clean dry air (CDA), N₂, or Ar for a purge dry process. Vacuum processing and/or spin-dry processing can alternatively or additionally be used to facilitate drying. Spin-dry processing works especially well in combination with one or more of the other above-listed drying processes, and may be performed in-situ. For example, a de-ionized water rinse can be dispensed through a nozzle to dissolve and/or clean any dirty fluid droplets, either contemporaneously with or followed immediately by a spin dry process.

At step 310, the wafer with the exposed and dry resist is heated for a post-exposure bake (PEB) for polymer dissolution. This step lets the exposed photo acid react with the polymer and make the polymer dissolution. The wafer may be heated to a temperature ranging between about 85° C. and about 150° C., possibly for a duration ranging between about 30 second and about 200 seconds, although other temperatures and durations are also within the scope of the preset disclosure. In some embodiments, the PEB step 310 can be preceded by a first lower-temperature bake (e.g., 80% of the temperature described above), which may help remove some of the existing fluid from the wafer.

At step 312, a pattern developing process is performed on the exposed (positive) or unexposed (negative) resist to leave the desired mask pattern. In some embodiments, the wafer is immersed in a developer liquid for a predetermined amount of time during which a portion of the resist is dissolved and removed. The wafer may be immersed in the developer solution for about 5 to about 60 seconds, for example. The composition of the developer solution is dependent on the composition of the resist, and is understood to be well known in the art.

The method 300 may also include one or more cleaning steps 302 prior to the resist form step 304 and/or one or more cleaning steps 314 after the develop step 312. For example, such optional step(s) may include cleaning at least a portion of at least one of the wafer stage, the immersion fluid (e.g., DI water) holder, a sensor, the lens and another component of the immersion exposure apparatus. The cleaning may employ a chemical cleaning solution including at least one of ammonia, hydrogen peroxide, ozone, sulfurous acid, and compositions thereof. Additionally, or alternatively, the cleaning may employ a surfactant solution including at least one of an ionic surfactant and a non-ionic surfactant. The cleaning steps 302 and/or 314 may be performed between each exposure, or on an as needed basis. The cleaning steps 302 and/or 314 may additionally or alternatively be performed at regular intervals, such as after a predetermined number of wafers processed by the lens, a predetermined number of cycles of filling and evacuation of the immersion fluid holder, or a predetermined number of exposures with the lens. The cleaning steps 302 and/or 314 may additionally or alternatively be performed when a measurement, characteristic, aspect or value sensed by a sensor exceeds a predetermined threshold, falls below a predetermined threshold, or otherwise satisfies a predetermined condition.

Thus, the present disclosure introduces an apparatus that is or includes an immersion exposure apparatus having, at least in one embodiment, a wafer stage, an immersion fluid (e.g., DI water) holder, a sensor and a lens, among other possible components. At least a portion of at least one of the wafer stage, the immersion fluid holder, the sensor, the lens and/or another component of the immersion exposure apparatus has an exterior coating selected from the group consisting of: (i) silicon dioxide; (ii) PTFE; (iii) fluoride; (iv) polyethylene; (v) polyvinylchloride; (vi) polymers of at least one of these materials; (vii) alloys of at least one of these materials; (viii) combinations containing at least one of these materials; and (ix) other polymers. Methods of making, manufacturing, using, operating or cleaning at least a portion of such apparatus are also within the scope of the present disclosure.

One embodiment of an apparatus constructed according to aspects of the present disclosure includes a plurality of components collectively operable or configured to perform immersion lithography, where the plurality of components includes one or more of a wafer stage, an immersion fluid (e.g., DI water) holder, a sensor, and a lens, among other possible components. At least a portion (e.g., one or more surfaces or regions thereon) of at least one of the plurality of components has an exterior coating configured to reduce contaminate adhesion. For example, the exterior coating may increase the contact angle of surfaces having the exterior coating, increase the degree to which surfaces having the exterior coating are hydrophilic, and/or decrease the degree to which surfaces having the exterior coating are hydrophobic.

The present disclosure also introduces a method including, at least in one embodiment, forming a photoresist (or resist) layer over a substrate, exposing the photoresist layer using immersion exposure apparatus, baking the exposed photoresist layer, and developing the baked, exposed photoresist layer. The immersion exposure apparatus includes a wafer stage, an immersion fluid (e.g., DI water) holder, a sensor and a lens. At least a portion of at least one of the wafer stage, the immersion fluid holder, the sensor and the lens has an exterior coating selected of silicon dioxide, PTFE, fluoride, polyethylene, polyvinylchloride, polymers of at least one of these materials, alloys of at least one of these materials, combinations containing at least one of these materials, and/or other polymers.

Embodiments of such a method may be performed for immersion lithography with reduced defect contamination. The method may also include cleaning at least a portion of at least one of the wafer stage, the DI water holder, the sensor, the lens and/or another component of the immersion exposure apparatus. The present disclosure also provides embodiments of apparatus operable or configured to perform at least a portion of at least one of the above methods.

One or more aspects of one or more embodiments of methods and/or apparatus within the scope of the present disclosure may render the immersion lens chamber free from defect adhesion, or decreased defect adhesion. One or more such aspects can additionally or alternatively decrease cross contamination among the lens, the resist, sensors, the stage, and/or the immersion fluid holder. One or more such aspects can additionally or alternatively decrease apparatus maintenance frequency and/or complexity. One or more such aspects can additionally or alternatively render the resist surface free from defects and/or watermark contamination, or reduce defects and/or watermark contamination. One or more such aspects can additionally or alternatively extend or increase wafer scan speed, possibly improving throughput. One or more such aspects can additionally or alternatively decrease or release resilient leaching spec. One or more such aspects can additionally or alternatively reduce or eliminate the need for TAR coating, and/or reduce TARC processing and associated cost and throughput.

Although embodiments of the present disclosure have been described in detail, those skilled in the art should understand that they can make various changes, substitutions and alterations herein without departing from the spirit and scope of the present disclosure.

We claim:

1. A method for performing immersion lithography, comprising:
coating one or more surfaces of an immersion lithography system with a hydrophilic coating, the one or more surfaces for containing an immersion fluid;
providing the immersion fluid to the immersion lithography system;
performing immersion lithography on a resist-coated substrate using the immersion lithography system with the one or more hydrophilic coated surfaces.

2. The method of claim 1 wherein the hydrophilic coating is selected from the group consisting of:
(i) silicon dioxide;
(ii) polytetrafluoroethylene;
(iii) fluoride;
(iv) polyethylene;
(v) polyvinylchloride;
(vi) polymers of at least one of the materials (i)-(v) above;
(vii) alloys of at least one of the materials (i)-(v) above; and
(viii) combinations containing at least one of the materials (i)-(v) above.

3. The method of claim 1 wherein the resist-coated substrate is a semiconductor wafer.

4. The method of claim 1 wherein the immersion lithography system includes a wafer stage, an immersion fluid holder, and a lens, and at least a portion of the immersion fluid holder is coated with the hydrophilic coating.

5. The method of claim 4 wherein each of the wafer stage, immersion fluid holder, and lens are coated with the hydrophilic coating.

6. The method of claim 4 further comprising:
cleaning at least a portion of at least one of the wafer stage, the immersion fluid holder, and the lens of the immersion exposure apparatus after performing the immersion lithography.

7. The method of claim 4 further comprising:
cleaning at least a portion of at least one of the wafer stage, the immersion fluid holder, and the lens of the immersion exposure apparatus when a value sensed by a sensor exceeds a predetermined threshold.

8. The method of claim 4 further comprising:
cleaning at least a portion of at least one of the wafer stage, the immersion fluid holder, and the lens of the immersion exposure apparatus using a chemical cleaning solution and a surfactant solution.

9. The method of claim 8, wherein the chemical cleaning solution includes at least one of ammonia, hydrogen peroxide, ozone, sulfurous acid, and compositions thereof.

10. The method of claim 8, wherein the surfactant solution includes at least one of an ionic surfactant and a non-ionic surfactant.

11. An immersion lithography system comprising:
an immersion fluid containment chamber including a plurality of surfaces;
an immersion fluid positioned in the immersion fluid containment chamber;
a substrate stage positioned within the immersion fluid chamber;
a lens; and
a reduced-contaminate-adhesion coating applied to one or more of the plurality of surfaces.

12. The immersion lithography system of claim 11 wherein the reduced-contaminate-adhesion coating is selected from the group consisting of:
(i) silicon dioxide;
(ii) polytetrafluoroethylene;
(iii) fluoride;
(iv) polyethylene;
(v) polyvinylchloride;
(vi) polymers of at least one of the materials (i)-(v) above;
(vii) alloys of at least one of the materials (i)-(v) above; and
(viii) combinations containing at least one of the materials (i)-(v) above.

13. The immersion lithography system of claim 11 wherein the substrate stage is configured for holding a resist-coated semiconductor wafer.

14. The immersion lithography system of claim 11 further comprising:
a reduced-contaminate-adhesion coating applied to at least a portion of the substrate stage.

15. The immersion lithography system of claim 11 further comprising:
a reduced-contaminate-adhesion coating applied to at least a portion of the lens.

16. The immersion lithography system of claim 11 further comprising:
a mechanism for providing a cleaning solution to the immersion fluid containment chamber.

17. The immersion lithography system of claim 16 further comprising:
a sensor for detecting when the cleaning solution should be provided to the immersion fluid containment chamber.

18. The immersion lithography system of claim 16, wherein the cleaning solution includes at least one of ammonia, hydrogen peroxide, ozone, sulfurous acid, and compositions thereof.

19. The immersion lithography system of claim 16, wherein the cleaning solution includes at least one of an ionic surfactant and a non-ionic surfactant.

20. An immersion lithography system comprising:
an immersion fluid holder for containing an immersion fluid;
a stage for positioning a resist-coated semiconductor wafer in the immersion fluid holder;
a sensor proximate to the immersion fluid holder; and
a lens proximate to the immersion fluid holder and positionable for projecting an image through the immersion fluid and onto the resist-coated semiconductor wafer;
wherein the immersion fluid holder includes a coating configured to reduce contaminate adhesion from contaminates in the immersion fluid.

21. The immersion lithography system of claim 20, wherein the coating includes a property for increasing a wettability of a surface of the immersion fluid holder that is adjacent to the immersion fluid.

22. An apparatus comprising:
a plurality of components collectively operable to perform immersion lithography, the plurality of components including one or more components selected from the group consisting of: a wafer stage, an immersion fluid holder, a sensor, and a lens;
wherein at least a portion of at least one of the plurality of immersion exposure apparatus components has an exterior coating configured to have a contact angle larger than about 50 degrees.

23. The apparatus of claim 22, wherein the coating is selected from the group consisting of:
(i) silicon dioxide;
(ii) polytetrafluoroethylene;
(iii) fluoride;
(iv) polyethylene;
(v) polyvinylchloride;
(vi) polymers of at least one of the materials (i)-(v) above;
(vii) alloys of at least one of the materials (i)-(v) above; and
(viii) combinations containing at least one of the materials (i)-(v) above.
